(19) United States
(12) Patent Application Publication
(10) Pub. No.: US 2026/0305284 A1
(43) Pub. Date: Oct. 1, 2026

(54) METHOD FOR FABRICATING DUAL-VIA PATTERN DAMASCENE STRUCTURE

(71) Applicant: Huahong Integrated Circuit(Chengdu) Corporation, Chengdu City (CN)

(72) Inventor: Xiaobo GUO, Chengdu City (CN)

(73) Assignee: Huahong Integrated Circuit(Chengdu) Corporation, Chengdu City (CN)

(21) Appl. No.: 19/565,352

(22) Filed: Mar. 12, 2026

(30) Foreign Application Priority Data
Mar. 31, 2025 (CN) 202510393113.0

(51) Int. Cl. H10W 20/00; H10P 76/20

(52) U.S. Cl. CPC H10W 20/085; H10P 76/2041

(57) ABSTRACT

The disclosure provides a method for fabricating a dual-via pattern damascene structure. A first via photoresist pattern is formed by using a photoresist layer. A silicon-containing anti-reflection layer and a spin-on carbon layer at via locations of the first via pattern are sequentially etched, stopping on a dielectric film layer. Subsequently, a directed self-assembly material is coated on a wafer, where the directed self-assembly material is a block copolymer material. A second via pattern is then formed through microphase separation of the directed self-assembly material. Only the first via pattern utilizes lithography technology, thereby saving one lithography process and reducing the cost. The second via pattern is formed by the microphase separation of the directed self-assembly material, which is a self-aligned process, improving overlay accuracy and enabling miniaturization of the second via pattern based on the first via pattern, thereby allowing for the formation of a smaller second via pattern.

### CROSS-REFERENCE TO RELATED APPLICATIONS

This application claims priority to Chinese patent application No. 2025103931130, filed on Mar. 31, 2025, the disclosure of which is incorporated herein by reference in its entirety.

### TECHNICAL FIELD

The present disclosure relates to the field of semiconductor integrated circuit fabrication technology, and particularly, to a method for fabricating a dual-via pattern damascene structure.

### BACKGROUND

In integrated circuit fabrication processes, a dual-damascene process is commonly employed to interconnect metal lines and vias. The structure in this process is shown in FIG. 1, which includes a trench pattern (metal line) and a via pattern (via). However, in certain specialized integrated circuit processes, it is necessary to connect a via to another via. In such cases, a dual-via pattern damascene structure, as shown in FIG. 2, is required. This structure includes two via patterns, one larger and one smaller. FIG. 3 shows one of conventional process flows for fabricating a dual-via pattern damascene structure. It generally includes steps such as growth of a dielectric film layer and a hard mask layer, first via pattern lithography, hard mask layer etching, second via pattern lithography, and all-in-one etching.

The aforementioned conventional process for fabricating the dual-via pattern damascene structure suffers from three main drawbacks. First, it requires two lithography processes, leading to higher costs. Second, it imposes stringent requirements for overlay accuracy during the lithography process of the second via pattern. Third, limited by the capabilities of lithography technology, the size of the second via pattern cannot be reduced below 400 Å.

### SUMMARY

A method for fabricating dual-via pattern damascene structure provided in the present disclosure includes the following steps:
S1: providing a substrate 100, and growing a dielectric film layer 200 on the substrate;
S2: forming a spin-on carbon layer 300, a silicon-containing anti-reflection layer 400, and a photoresist layer 500 sequentially from bottom to top on the dielectric film layer 200, and performing a first via pattern lithography process to form a first via photoresist pattern in the photoresist layer 500;
S3: sequentially performing etching on the silicon-containing anti-reflection layer 400 and the spin-on carbon layer 300 at via locations of the first via pattern by using the photoresist layer 500 as a mask, stopping on the dielectric film layer 200;
S4: removing the photoresist layer 500, and then coating a directed self-assembly material 600 on a wafer, where
the directed self-assembly material 600 is a polymer formed by connecting a polystyrene homopolymer and a poly methyl methacrylate homopolymer through a covalent bond; and etch selectivity ratios of the poly methyl methacrylate homopolymer and the polystyrene homopolymer are between 3:1 and 10:1;
S5: performing baking on the directed self-assembly material 600 to cause microphase separation of a polystyrene layer 601 and a poly methyl methacrylate layer 602, where the polystyrene layer 601 is formed on surfaces of the silicon-containing anti-reflection layer 400 and the spin-on carbon layer 300, and encapsulates the poly methyl methacrylate layer 602 within a central region of the via locations of the first via pattern;
S6: performing etching-back on the directed self-assembly material after microphase separation, exposing an upper surface of the poly methyl methacrylate layer 602 encapsulated by the polystyrene layer 601;
S7: performing etching on the directed self-assembly material to cause the poly methyl methacrylate layer 602 to be completely removed by using the different etch rate of the poly methyl methacrylate homopolymer and the polystyrene homopolymer, exposing the dielectric film layer 200 located beneath the poly methyl methacrylate layer 602, while simultaneously retaining a portion of the polystyrene layer 601 on sidewalls of the spin-on carbon layer 300, where a second via is formed within the retained portion of the polystyrene layer 601; and
S8: performing etching on the dielectric film layer 200 by using the second via to expose the substrate 100 beneath the dielectric film layer at the location of the second via, removing the retained portion of the polystyrene layer 601 at the via locations of the first via pattern and thinning the dielectric film layer beneath the retained portion of the polystyrene layer 601, thereby forming the dual-via pattern damascene structure 700.

Preferably, in step S1, before growing the dielectric film layer 200, one or more process steps have been completed on the substrate 100.

Preferably, the dielectric film layer 200 is a single-layer film or includes a combination of multiple film layers.

Preferably, in step S2, the silicon-containing anti-reflection layer 400 has a thickness greater than 100 Å.

Preferably, in step S4, before coating the directed self-assembly material 600, the substrate undergoes a pretreatment;
the pretreatment includes baking, rinsing with an organic solvent, and coating a polystyrene material.

Preferably, in step S5, the directed self-assembly material 600 is baked at a temperature ranging from 150° C. to 300° C. for a duration ranging from 60 seconds to 500 seconds.

Preferably, the etching in steps S6, S7, and S8 is performed by adopting an all-in-one etching method, whereby the etching in all three steps is completed within a same tool by adjusting etching parameter to meet the requirements of etching in different steps.

Preferably, after step S8, the method further includes a step S9 of removing the spin-on carbon layer 300 and the silicon-containing anti-reflection layer 400.

In the method for fabricating the dual-via pattern damascene structure according to the present disclosure, the photoresist layer 500 is used to form the first via photoresist pattern. Using the photoresist layer 500 as a mask, the silicon-containing anti-reflection layer 400 and the spin-on carbon layer 300 at the via locations of the first via pattern are etched sequentially, stopping on the dielectric film layer 200. After removing the photoresist layer 500, a directed self-assembly material 600 is coated on the wafer. The directed self-assembly material 600 is a block copolymer material, a special type of polymer formed by connecting two or more different homopolymers via covalent bonds. A second via pattern is then formed through microphase separation of the directed self-assembly material. Only the first via pattern utilizes lithography technology, thereby saving one lithography process and reducing the cost. The second via pattern is formed via microphase separation of the directed self-assembly material. Relative to the first via pattern, this is a self-aligned process. Consequently, compared to the conventional processes, the overlay accuracy is significantly improved. Further, because the second via pattern is formed through microphase separation of the directed self-assembly material, it is miniaturized relative to the first via pattern. Therefore, compared to the conventional processes, a smaller second via pattern can be obtained (the size of the second via pattern can be less than 400 Å).

### BRIEF DESCRIPTION OF THE DRAWINGS

In order to more clearly describe the technical solutions in the present disclosure, the following will briefly introduce the drawings needed in the present disclosure. It is obvious that the drawings in the following description are only some embodiments of the present disclosure. Those skilled in the art may obtain other drawings from these drawings without contributing any inventive labor.

FIG. 1 shows a dual-damascene structure including a trench pattern (metal line) and a via pattern (via).

FIG. 2 shows a damascene structure formed by dual via patterns.

FIG. 3 shows a conventional process flow for fabricating a dual-via pattern damascene structure.

FIG. 4 to FIG. 11 are sectional views showing respective process steps of a method for fabricating a dual-via pattern damascene structure according to the present disclosure.

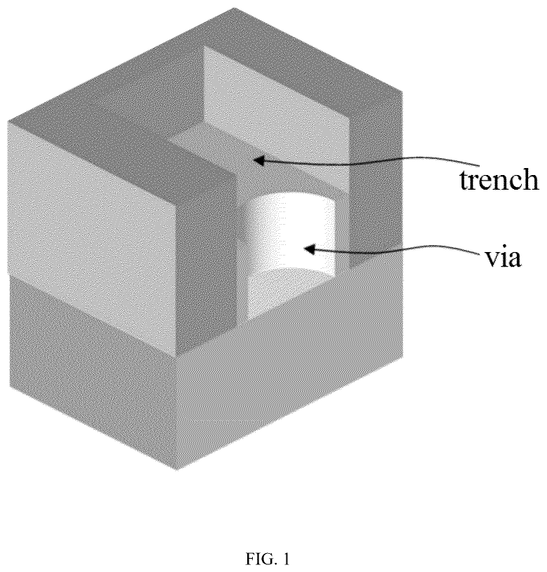

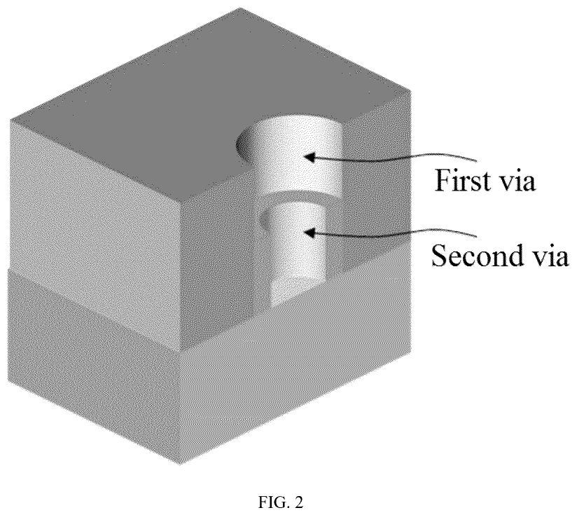

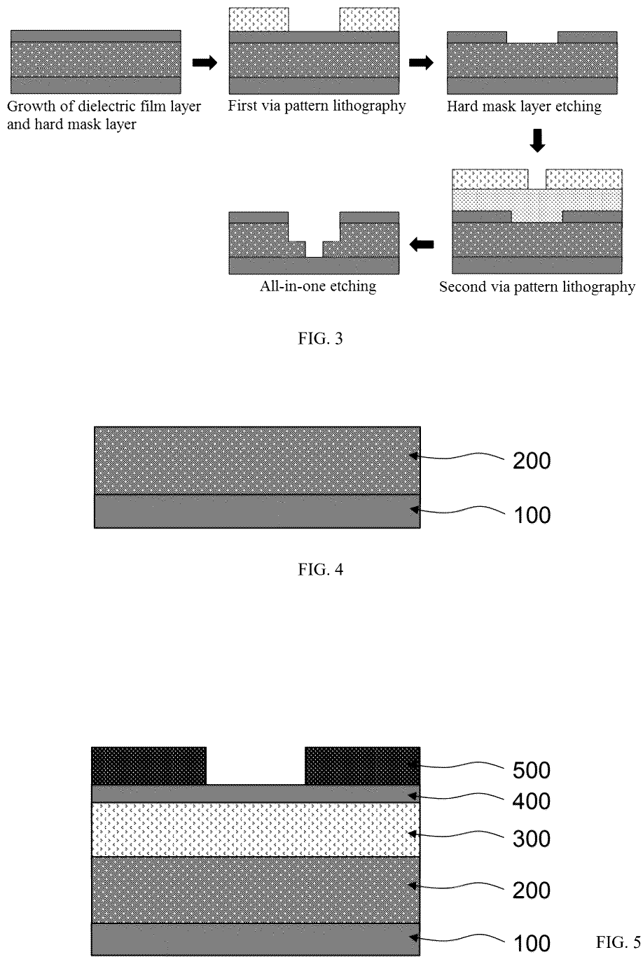

### DESCRIPTION OF REFERENCE SIGNS

100—substrate; 200—dielectric film layer; 300—spin-on carbon layer; 400—silicon-containing anti-reflection material; 500—photoresist layer; 600—directed self-assembly material; 601—polystyrene layer after microphase separation; 602—poly methyl methacrylate layer after microphase separation; 700—dual-via pattern damascene structure.

### DETAILED DESCRIPTION OF THE EMBODIMENTS

The technical solutions in the embodiments of the present disclosure will be clearly and completely described below with reference to the drawings in the embodiments of the present disclosure. Apparently, the described embodiments are merely some rather than all of the embodiments of the present disclosure. All other embodiments obtained by those skilled in the art based on the embodiments of the present disclosure without contributing any inventive labor shall still fall within the scope of protection of the present disclosure.

Words such as “first”, “second” and the like used in the present disclosure do not indicate any order, quantity, or importance, but are only intended to distinguish different components. Words such as “comprising” or “including” refer to a component or object that appears before the word, including those listed after the word and their equivalents, without excluding other components or objects. Words like “connecting” or “connected” are not limited to physical or mechanical connections, but may include electrical connections, whether direct or indirect. “Up”, “down”, “left”, “right”, and the like are only intended to represent relative positional relationships. When the absolute position of a described object changes, the relative positional relationship may also change correspondingly.

It is to be understood that, without conflict, the embodiments and features in the embodiments of the present disclosure may be freely combined with each other.

### Embodiment 1

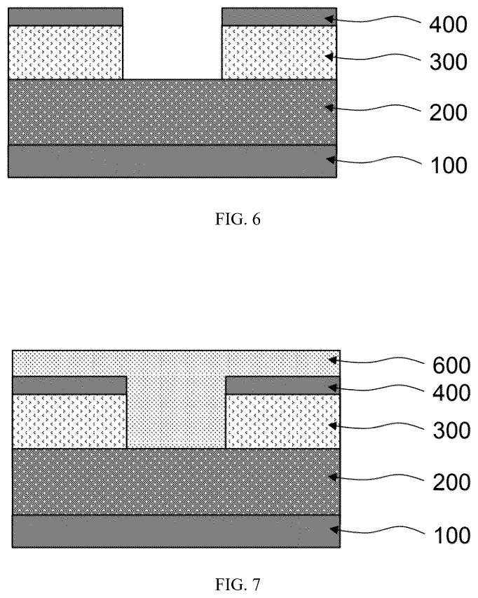

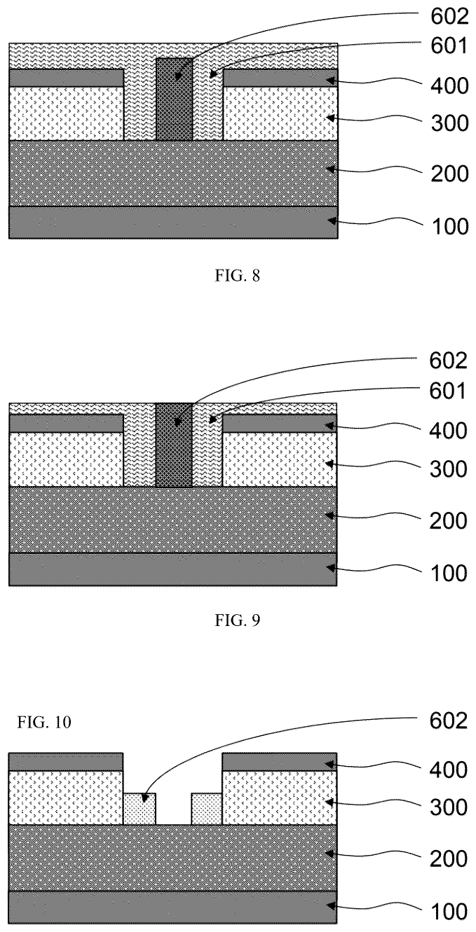

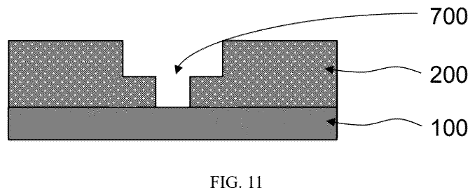

A method for fabricating a dual-via pattern damascene structure includes the following steps:
S1: providing a substrate 100, and growing a dielectric film layer 200 on the substrate, as shown in FIG. 4;
S2: forming a spin-on carbon layer 300, a silicon-containing anti-reflection layer 400, and a photoresist layer 500 sequentially from bottom to top on the dielectric film layer 200, and performing a first via pattern lithography process to form a first via photoresist pattern in the photoresist layer 500, as shown in FIG. 5;
S3: sequentially performing etching on the silicon-containing anti-reflection layer 400 and the spin-on carbon layer 300 at via locations of the first via pattern by using the photoresist layer 500 as a mask, stopping on the dielectric film layer 200, as shown in FIG. 6;
S4: removing the photoresist layer 500, and then coating a directed self-assembly material 600 on a wafer, as shown in FIG. 7, where
the directed self-assembly material 600 is a polymer formed by connecting a polystyrene (PS) homopolymer and a poly methyl methacrylate (PMMA) homopolymer through a covalent bond; and etch selectivity ratios of the poly methyl methacrylate homopolymer and the polystyrene homopolymer are between 3:1 and 10:1;
S5: performing baking on the directed self-assembly material 600 to cause microphase separation of a polystyrene layer 601 and a poly methyl methacrylate layer 602, where the polystyrene layer is formed on surfaces of the silicon-containing anti-reflection layer 400 and the spin-on carbon layer 300, and encapsulates the poly methyl methacrylate layer 602 within a central region of the via locations of the first via pattern, as shown in FIG. 8;
S6: performing etching-back on the directed self-assembly material (primarily the polystyrene layer 601) after microphase separation, exposing an upper surface of the poly methyl methacrylate layer 602 encapsulated by the polystyrene layer 601, as shown in FIG. 9;
S7: performing etching on the directed self-assembly material (the polystyrene layer 601 and the poly methyl methacrylate layer 602) to cause the poly methyl methacrylate layer 602 to be completely removed by using the different etch rate of the poly methyl methacrylate homopolymer and the polystyrene homopolymer, exposing the dielectric film layer 200 located beneath the poly methyl methacrylate layer 602, while simultaneously retaining a portion of the polystyrene layer 601 on sidewalls of the spin-on carbon layer 300, where a second via is formed within the retained portion of the polystyrene layer 601; Due to the etch selectivity ratios of the poly methyl methacrylate homopolymer and the polystyrene homopolymer being between 3:1 and 10:1, after the poly methyl methacrylate layer 602 is completely etched, a portion of the polystyrene layer 601 remains, and the second via is formed within the remaining portion of the polystyrene layer 601, as shown in FIG. 10; and
S8: performing etching on the dielectric film layer 200 by using the second via to expose the substrate 100 beneath the dielectric film layer at the location of the second via, removing the retained portion of the polystyrene layer 601 at the via locations of the first via pattern and thinning the dielectric film layer beneath the retained portion of the polystyrene layer 601, thereby forming the dual-via pattern damascene structure 700, as shown in FIG. 11.

In the dual-via pattern damascene structure, the smaller via is located beneath the larger via, forming a dual-via pattern damascene structure that is larger on top and smaller at the bottom.

Preferably, in step S1, before growing the dielectric film layer 200, one or more process steps have been completed on the substrate 100.

Preferably, the dielectric film layer 200 is a single-layer film or includes a combination of multiple film layers.

In the method for fabricating the dual-via pattern damascene structure according to Embodiment 1, the photoresist layer 500 is used to form the first via photoresist pattern. Using the photoresist layer 500 as a mask, the silicon-containing anti-reflection layer 400 and the spin-on carbon layer 300 at the via locations of the first via pattern are etched sequentially, stopping on the dielectric film layer 200. After removing the photoresist layer 500, a directed self-assembly material 600 is coated on the wafer. The directed self-assembly material 600 is a block copolymer material, a special type of polymer formed by connecting two or more different homopolymers via covalent bonds. A second via pattern is then formed through microphase separation of the directed self-assembly material. Only the first via pattern utilizes lithography technology, thereby saving one lithography process and reducing the cost. The second via pattern is formed via microphase separation of the directed self-assembly material. Relative to the first via pattern, this is a self-aligned process. Consequently, compared to the conventional processes, the overlay accuracy is significantly improved. Further, because the second via pattern is formed through microphase separation of the directed self-assembly material, it is miniaturized relative to the first via pattern. Therefore, compared to the conventional processes, a smaller second via pattern can be obtained (the size of the second via pattern can be less than 400 Å).

### Embodiment 2

Based on the method for fabricating the dual-via pattern damascene structure according to Embodiment 1, in step S4, before coating the directed self-assembly material 600, the substrate undergoes a pretreatment;
the pretreatment includes baking, rinsing with an organic solvent, coating a polystyrene material, and the like.

Preferably, in step S2, the silicon-containing anti-reflection layer 400 has a thickness greater than 100 Å.

Preferably, in step S5, the directed self-assembly material 600 is baked at a temperature ranging from 150° C. to 300° C. for a duration ranging from 60 seconds to 500 seconds.

### Embodiment 3

Based on the method for fabricating the dual-via pattern damascene structure according to Embodiment 1, the etching in steps S6, S7, and S8 is performed by adopting an all-in-one etching method, whereby the etching in all three steps is completed within a same tool by adjusting etching parameter to meet the requirements of etching in different steps.

Preferably, after step S8, the method further includes a step S9 of removing the spin-on carbon layer 300 and the silicon-containing anti-reflection layer 400.

What are described above are only exemplary embodiments of the present disclosure, and are not intended to limit the present disclosure. Any modifications, equivalent replacements, improvements and the like made within the spirit and principle of the present disclosure shall all be included in the scope of protection of the present disclosure.

What is claimed is:

1. A method for fabricating a dual-via pattern damascene structure, comprising the following steps:
S1: providing a substrate, and growing a dielectric film layer on the substrate;
S2: forming a spin-on carbon layer, a silicon-containing anti-reflection layer, and a photoresist layer sequentially from bottom to top on the dielectric film layer, and performing a first via pattern lithography process to form a first via photoresist pattern in the photoresist layer;
S3: sequentially performing etching on the silicon-containing anti-reflection layer and the spin-on carbon layer at via locations of the first via pattern by using the photoresist layer as a mask, stopping on the dielectric film layer;
S4: removing the photoresist layer, and then coating a directed self-assembly material on a wafer, wherein
the directed self-assembly material is a polymer formed by connecting a polystyrene homopolymer and a poly methyl methacrylate homopolymer through a covalent bond; and
etch selectivity ratios of the poly methyl methacrylate homopolymer and the polystyrene homopolymer are between 3:1 and 10:1;
S5: performing baking on the directed self-assembly material to cause microphase separation of a polystyrene layer and a poly methyl methacrylate layer, wherein the polystyrene layer is formed on surfaces of the silicon-containing anti-reflection layer and the spin-on carbon layer, and encapsulates the poly methyl methacrylate layer within a central region of the via locations of the first via pattern;
S6: performing etching-back on the directed self-assembly material after microphase separation, exposing an upper surface of the poly methyl methacrylate layer encapsulated by the polystyrene layer;
S7: performing etching on the directed self-assembly material to cause the poly methyl methacrylate layer to be completely removed by using the different etch rate of the poly methyl methacrylate homopolymer and the polystyrene homopolymer, exposing the dielectric film layer located beneath the poly methyl methacrylate layer, while simultaneously retaining a portion of the polystyrene layer on sidewalls of the spin-on carbon layer, wherein a second via is formed within the retained portion of the polystyrene layer; and
S8: performing etching on the dielectric film layer by using the second via to expose the substrate beneath the dielectric film layer at the location of the second via, removing the retained portion of the polystyrene layer at the via locations of the first via pattern and thinning the dielectric film layer beneath the retained portion of the polystyrene layer, thereby forming the dual-via pattern damascene structure.

2. The method according to claim 1, wherein
In step S1, before growing the dielectric film layer, one or more process steps have been completed on the substrate.

3. The method according to claim 1, wherein
the dielectric film layer is a single-layer film or comprises a combination of multiple film layers.

4. The method according to claim 1, wherein
in step S2, the silicon-containing anti-reflection layer has a thickness greater than 100 Å.

5. The method according to claim 1, wherein
in step S4, before coating the directed self-assembly material, the substrate undergoes a pretreatment;
the pretreatment comprises baking, rinsing with an organic solvent, and coating a polystyrene material.

6. The method according to claim 1, wherein
in step S5, the directed self-assembly material is baked at a temperature ranging from 150° C. to 300 °C for a duration ranging from 60 seconds to 500 seconds.

7. The method according to claim 1, wherein
the etching in steps S6, S7, and S8 is performed by adopting an all-in-one etching method, whereby the etching in all three steps is completed within a same tool by adjusting etching parameter to meet the requirements of etching in different steps.

8. The method according to claim 1, wherein
after step S8, the method further comprises a step S9 of removing the spin-on carbon layer and the silicon-containing anti-reflection layer.
